(19) United States
(12) Patent Application Publication
(10) Pub. No.: US 2002/0064731 A1
(43) Pub. Date: May 30, 2002

(54) Radiation-sensitive mixture and production of relief structures

(76) Inventor: Son Nguyen Kim, Hemsbach (DE)

Correspondence Address: Herbert B. Keil, 1101 Connecticut Ave., N.W., Washington, DC, 20036, US

(21) Appl. No.: 10/056,395

(22) Filed: Jan. 28, 2002

Related U.S. Application Data
(62) Division of application No. 07/608,755, filed on Nov. 5, 1990.

(30) Foreign Application Priority Data
Dec. 30, 1989 (DE) P 39 43 413.3

(51) Int. Cl. G03F 7/038; G03F 7/32; G03F 7/38; G03F 7/40

(52) U.S. Cl. 430/325; 430/330; 430/914; 430/921; 430/270.1; 522/31

(57) ABSTRACT

A radiation sensitive mixture essentially consists of

(a) a binder or binder mixture which is insoluble in water but soluble in aqueous alkaline solutions,

(b) a compound which forms a strong acid on exposure to radiation and

(c) one or more organic compounds which are capable of undergoing condensation in the presence of acid,

each of the components (a), (b) and (c) containing one or more phenolic hydroxyl groups.

The said mixture is suitable for the production of relief structures.

The present invention relates to radiation-sensitive mixtures which are negative-working and contain a binder which is insoluble in water but soluble in aqueous alkaline solutions, a compound which forms an acid on exposure to radiation and organic compounds which are capable of undergoing condensation in the presence of acid. These mixtures are sensitive to UV radiation, electron beams and X-rays and are particularly suitable as resist material.

Negative-working radiation-sensitive mixtures and methods for image production by means of these mixtures are known. Negative-working photoresists are those in which, after imagewise exposure of the photosensitive layer and if necessary after an additional heat treatment, the exposed parts of this layer are insoluble in the developer in which they were soluble prior to exposure.

In general, negative-working photoresists are based on photopolymerizable mixtures which, in addition to a polymeric binder, contain a photopolymerizable compound and a photoinitiator. The most generally used negative-working photoresists for the production of integrated circuits contain almost without exception partially cyclized polyisoprene as a crosslinkable component and a diazide compound as a photosensitive bifunctional crosslinking agent. Diazides having the structure (A)

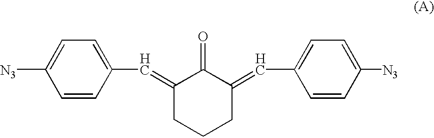

are very commonly used.

Recently, negative-working photoresists which consist of a partially cyclized polybutadiene and diazides have also become commercially available (cf. inter alia Harita, Y., Ichigawa, M. and Harada, K., Polym. Eng. Sci., 17 (1977), 372).

A number of negative-working photoresists are also based on photodimerization as a crosslinking reaction. These include the cinnamic acid derivatives and the chalcones which are structurally related to them. The crosslinking reaction takes place essentially as a photoinduced [2+2]cycloaddition with formation of cyclobutanes (cf. Williams, J. L. R.: Fortschr. Chem. Forsch. 13 (1969), 227; Reiser, A. and Egerton, P. L.: Photogr. Sci. Eng. 23 (1979), 144; M. Kato et al.: J. Polym. Sci. part B, Polym. Lett. Ed. 8 (1970), 263; M. Kato et al.: Photogr. Sci. Eng. 23 (1979), 207).

Recently, a type of photodimerizable epoxy resin which has long been known has also been used as a photoresist (cf. for example DE-A-14 47 016, DE-A-23 42 407, DE-A-25 53 346 and DE-A-24 49 926). These resins carry both groups which permit photocycloaddition reactions, for example chalcone radicals, and epoxy groups, which can be subsequently crosslinked under thermal catalysis (cf. Photoresist, New York, McGraw Hill (1975), British Patent 892,111 and U.S. Pat. No. 2,852,379).

Apart from the negative-working photoresists which contain a diazide of the abovementioned structure (A), the photochemical reactions are possible only in the NUV range (ie. at from 350 to 450 nm). Novel diazide compounds for the short wavelength UV range have been described in recent years. These include ketone compounds (cf. J. Electrochem. Soc. 128 (1981), 361) and sulfur-containing diazide compounds (cf. J. Electrochem. Soc. 127 (1980), 2759).

Negative-working photoresists which can be developed in aqueous alkaline media and can be provided with a structure in the short wavelength UV range are also known. Poly-(p-vinylphenol), as a binder, and 3,3′-diazidodiphenyl sulfone (cf. IEEE Trans. Electron Devices, ED. 28 (1981), 1306 and IEEE Trans. Electron Devices, ED.28 (1981), 1284) are used for this purpose. Another negative-working photoresist which can be developed in aqueous alkaline media is based on an onium salt and methyl acrylamidoglycolate methyl ether (cf. Hult et al., Polymers for High Tech. ACS Symposium Series 346 (1987), 162-169), which is based on the principle of acid-catalyzed autocondensation for crosslinking of the binder.

Another photopolymerizable composition which is based on an acid-curable material and an iodonium salt as an acid donor is disclosed in DE-A 2 602 574.

Acid-catalyzed crosslinking agents, including, for example, the arylmethylol compounds obtainable as intermediates for condensation of phenol/formaldehyde resin, are also known (cf. Progr. Org. Coat. 9 (1981), 107; DE-A-29 04 961; Plastics and Rubber Processing and Application 1 (1981), 39; DE-A-32 47 754; EP-A-01 39 309; JP 3051424-A). These acid-catalyzed crosslinking agents are also used for recording material which can be provided with a structure by a photochemical method. EP-A-0282724 reports a novel negative-working system which is based on poly-(p-hydroxystyrene), an acid donor and a crosslinking agent having two or more protected methylol-groups; instead of poly-(p-hydroxystyrene), m-cresol/formaldehyde resin can also be used. PCT/US 88/02878 has described another negative-working system in which furthermore poly-(p-hydroxystyrene) or m-cresol/formaldehyde novolaks are used as binders, a 1,2-quinonediazide is used as the acid donor and a 2,6-dimethylol-p-cresol is used as the crosslinking agent (cf. also Photopolymers, Principles, Processes and Materials, 63-72 (1988)). The disadvantages of the two abovementioned systems are a decrease in adhesion on overexposure and the formation of a residual layer, or too little sensitivity.

It is an object of the present invention to provide novel highly active radiation-sensitive systems for the production of layers which are photosensitive to short-wavelength UV light, can be developed using aqueous alkaline solutions and permit the production of structures in the submicron range which are stable to heat and to plasma.

We have found, surprisingly, that this object is very advantageously achieved by the combination of certain substances, all of which contain phenolic hydroxy groups.

The present invention relates to a radiation-sensitive mixture essentially consisting of

(a) a binder or binder mixture which is insoluble in water but soluble in aqueous alkaline solutions,

(b) a compound which forms a strong acid on exposure to radiation and

(c) one or more organic compounds which are capable of undergoing condensation in the presence of acid,

wherein each of the components (a), (b) and (c) contains one or more phenolic hydroxyl groups.

The binder (a) may preferably be a phenolic resin which has one or more free o- and/or p-positions on the phenol nuclei, a short-chain p-cresol/formaldehyde novolak having a mean molecular weight \overline{M}_{w} of from 150 to 1,500, a p-substituted cresol/formaldehyde novolak which essentially consists of units of the general formulae

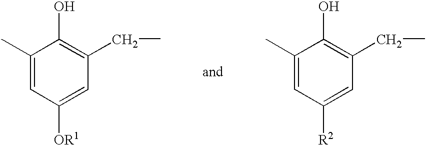

where R¹ is alkyl, aryl or aralkyl and R² is OR¹, alkyl or aralkyl, and has a mean molecular weight \overline{M}_{w} of from 200 to 5,000, in particular a poly-(p-hydroxystyrene) or poly-(p-hydroxy-_{α}-methylstyrene) having a mean molecular weight \overline{M}_{w} of from 200 to 30,000, or a mixture of two or more of the abovementioned binders and may be present in general in an amount of from 50 to 95% by weight, based on the total amount of radiation-sensitive mixture.

Preferably used compounds (b) which form a strong acid on exposure to radiation are onium salts of the general formula (I)

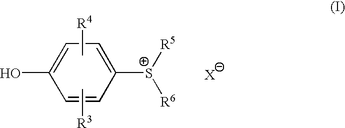

where R³ and R⁴ are identical or different and are each H, OH, alkyl or alkoxy of 1 to 4 carbon atoms, R⁴ and R⁵ are identical or different and are each methyl, ethyl, phenyl or radical

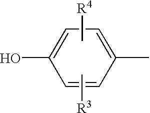

and X^{⊖} is AsF₆^{⊖}, PF₆^{⊖}, SbF₆^{⊖}, BF₄^{⊖} or CF₃SO₃^{⊖}, these components (b) generally being present in amounts of from not less than 1 to 30% by weight, based on the total amount of the radiation-sensitive mixture.

Organic compounds (c) which are capable of undergoing condensation in the presence of an acid are in particular compounds of the general formula (II)

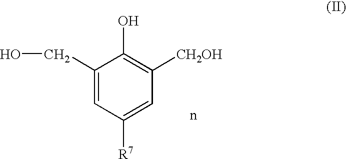

where R⁷ is alkyl of 1 to 4 carbon atoms and n is from 1 to 10, which are generally used in amounts of from not less than 3 to 30% by weight, based on the total amount of the radiation-sensitive mixture.

The novel mixture may additionally contain a sensitizer which absorbs radiation and transfers it to component (b), and not more than 1% by weight of additives from the group consisting of the adhesion promoters, surfactants and/or dyes.

The present invention furthermore relates to a process for the preparation of photosensitive coating materials, wherein a novel radiation-sensitive mixture is used, and a process for the production of relief structures by application of a radiation-sensitive mixture in a layer thickness of from 0.1 to 5 μm onto a conventionally pretreated substrate, drying at from 70 to 120° C., imagewise exposure, heating to 70-160° C. and development using an aqueous alkaline solution, wherein a novel radiation-sensitive mixture is used.

The novel radiation-sensitive mixtures have high sensitivity and good structure properties, in particular very good adhesion to silica surfaces.

Regarding the radiation-sensitive mixtures, their components and their use, the following may be stated specifically.

a) Suitable binders which are insoluble in water but soluble in aqueous alkaline solutions and contain one or more phenolic hydroxyl groups are phenolic resins, preferably those in which not less than 20%, preferably not more than 66%, of the ortho- and/or para-positions on the phenyl radicals are free of substituents, such as novolaks having mean molecular weights \overline{M}_{w} of from 200 to 5,000, preferably from 200 to 2,000, for example novolaks based on p-cresol/formaldehyde, in particular poly-(p-hydroxystyrenes), poly-(p-hydroxy-α-methylstyrenes), for example having mean molecular weights \overline{M}_{w} of from 200 to 30,000, preferably from 1,000 to 10,000, and mixtures of such phenolic resins.

Other examples of suitable novolaks are those described in Novolak Resins Used in Positive Resist Systems by T. Pampalone in Solid State Technology, June 1984, pages 115-120. For special applications, for example for exposure in the short-wavelength UV range, novolaks obtained from p-cresol and formaldehyde are preferred.

A preferred component (a) is poly-(p-hydroxystyrene).

The novel radiation-sensitive mixtures contain component (a) in general in amounts of from 50 to 95, preferably from 70 to 90, percent by weight, based on the total amount of the radiation-sensitive mixture.

Suitable acid donors (b) are all compounds which have one or more phenolic hydroxyl groups and form a strong acid on exposure to radiation. However, sulfonium salts of the general formula (I)

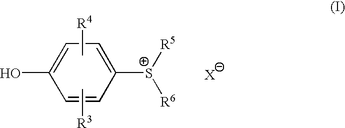

where R³ and R⁴ are identical or different and are each H, OH, alkyl of 1 to 4 carbon atoms, preferably 1 carbon atom, or alkoxy of 1 to 4 carbon atoms, preferably methoxy or ethoxy, R⁵ and R⁶ are identical or different and are each alkyl of 1 to 3 carbon atoms, eg. methyl or ethyl, phenyl or the radical

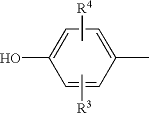

and X^{⊖} is AsF₆^{⊖}, SbF₆^{⊖}, PF₆^{⊖}, ClO₄^{⊖}, BF₄^{⊖} and/or CF₃SO₃^{⊖} (=triflate), are preferred for exposure in the short-wavelength range.

Examples of particularly advantageous sulfonium salts are

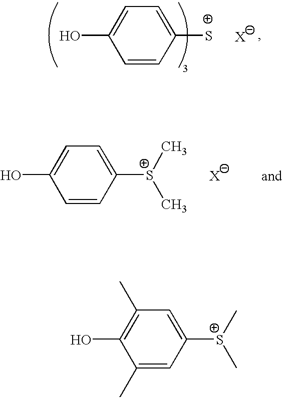

where X^{⊖} is AsF₆^{⊖}, PF₆^{⊖} or CF₃SO₃^{⊖}.

Other acid donors may also be used as component (b), for example corresponding iodonium compounds having phenolic hydroxyl groups.

Component (b) is present in the novel radiation-sensitive mixture in general in amounts of from not less than 1 to 30, preferably from 3 to 15, percent by weight, based on the total amount of the radiation-sensitive mixture.

Suitable organic compounds (c) capable of undergoing condensation in the presence of an acid are preferably compounds of the general formula (III)

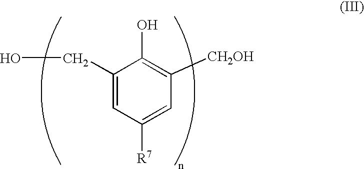

where R⁷ is alkyl of 1 to 4 carbon atoms, preferably methyl, and n is from 1 to 10, preferably 1. Such organic compounds (c) can be obtained, for example, by reacting phenol with formaldehyde under alkaline conditions (cf. also Ruderman, Ind. Eng. Chem. Anal. 18 (1946), 753, and Auwers, Berichte 40 (1907), 2524).

Component (c) is present in the novel radiation-sensitive mixture in general in an amount of not less than 3 to 30, preferably from 5 to 25, % by weight, based on the total amount of radiation-sensitive mixture, the sum of the percentages stated under (a), (b) and (c) being 100 in each case.

The novel mixtures are preferably dissolved in an organic solvent, the solids content generally being from 5 to 40% by weight. Preferred solvents are aliphatic ketones, ethers and mixtures thereof, in particular ethylcellosolve, butylglycol, methylcellosolve and 1-methoxy-2-propanol, alkylene glycol alkyl ether esters, for example methylcellosolve acetate, ethylcellosolve acetate, methyl propylene glycol acetate and ethyl propylene glycol acetate, ketones, for example cyclohexanone, cyclopentanone and methyl ethyl ketone, acetates, such as butyl acetate, and aromatics, such as toluene and xylene. The choice of the corresponding solvents and mixtures thereof depends on the choice of the particular phenolic polymer, novolak and photosensitive components.

Other additives, such as adhesion promoters, wetting agents, dyes and plasticizers, may also be added.

If necessary, sensitizers may also be added in small amounts in order to sensitize the compounds in the longer wavelength UV range up to the visible range. Polycyclic aromatics, such as pyrene and perylene, are preferred for this purpose, but other dyes which act as sensitizers may also be used.

The solution of the novel radiation-sensitive mixture can be filtered through a filter having a pore diameter of 0.2 μm.

A resist film having a layer thickness of from 0.1 to 5 μm can be produced on a wafer (for example a surface-oxidized silicon wafer) by applying the solution of the novel radiation-sensitive mixture (=resist solution) by spin coating at speeds of from 1,000 to 10,000 rpm. The wafer coated in this manner is then dried for from 1 to 5 minutes at 90° C. or 80° C. (for example on a hotplate).

In the novel process for the production of relief images, a radiation-sensitive recording layer which essentially consists of the novel radiation-sensitive mixture is exposed imagewise to a dose such that the solubility of the exposed parts in aqueous alkaline solvents increases heating step at from 70 to 160° C., and these parts can be selectively removed using the alkaline developer.

The resist films are exposed to UV light from a mercury lamp, to excimer laser light, to electron beams or to X-rays, for example through a chromium-plated structured quartz mask. The films exposed imagewise can then be heated, for example, for from 5 seconds to 5 minutes at from 110 to 120° C. and then developed with an aqueous alkaline developer, the exposed parts selectively becoming detached while little removal of material takes place in the unexposed parts.

Particular advantages of the novel radiation-sensitive mixture are its excellent reproducibility and the very good structure properties, in the submicron range, of the relief produced using the said mixture.

In the Examples which follow, parts and percentages are by weight unless stated otherwise.

### EXAMPLE 1

A photoresist solution is prepared from 85 parts of poly-(p-hydroxystyrene) (from Polysciences, \overline{M}_{w}=1,500-71000), 5 parts of tri-(p-hydroxyphenyl)-sulfonium hexafluoroarsenate, 10 parts of 2,6-dimethylol-p-cresol and 280 parts of methylglycol acetate. The solution is then filtered through a filter having a pore diameter of 0.2 μm.

The resist solution is applied to an oxidized silicon wafer in a layer thickness of 1 μm by spin coating and the layer is dried on a hotplate for one minute at 90° C. and then exposed for 2 seconds to an excimer laser of wavelength λ=248 nm through a test mask by the contact method. Thereafter, the wafer is heated at 120° C. for 1 minute and is developed using a developer of pH 12.5-14.5. The sensitivity for 1 Am layer thickness is ˜20 mJ/cm².

### EXAMPLE 2

A photoresist solution is prepared from 88 parts of p-cresol/formaldehyde novolak (\overline{M_{w}}=200-300), 3 parts of tri-(p-hydroxyphenyl)-sulfonium hexafluoroarsenate, 9 parts of 2,6-dimethylol-p-cresol and 280 parts of cyclohexanone. The procedure described in Example 1 is followed. The sensitivity for 1 μm layer thickness is ˜50 mJ/cm².

### EXAMPLE 3

A photoresist solution is prepared from 85 parts of p-methoxyphenol/formaldehyde novolak (\overline{M_{w}}=1,000-1,500), 6 parts of tri-(p-hydroxyphenyl)-sulfonium triflate, 9 parts of 2,6-dimethylol-p-cresol and 280 parts of diglyme (=diethylene glycol dimethyl ether). The procedure described in Example 1 is followed. The sensitivity for 1 μm layer thickness is ˜30 mJ/cm².

We claim:

1. A radiation-sensitive mixture essentially consisting of
(a) a binder or binder mixture which is insoluble in water but soluble in aqueous alkaline solutions,
(b) a compound which forms a strong acid on exposure to radiation and
(c) one or more organic compounds which are capable of undergoing condensation in the presence of acid,
wherein each of the components (a), (b) and (c) contains one or more phenolic hydroxyl groups.

2. A radiation-sensitive mixture as claimed in claim 1, wherein the binder (a) is a phenolic resin which has one or more free o- and/or p-positions on the phenol nuclei.

3. A radiation-sensitive mixture as claimed in claim 1, wherein the binder (a) is a short-chain p-cresol/formaldehyde novolak having a mean molecular weight \overline{M}_{w} of from 150 to 1,500.

4. A radiation-sensitive mixture as claimed in claim 1, wherein the binder (a) is a p-substituted cresol/formaldehyde novolak which essentially consists of units of the formulae 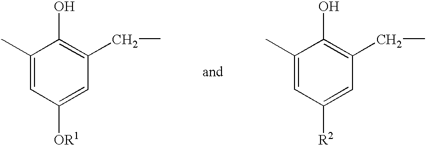
where R¹ is alkyl, aryl or aralkyl and R² is ore, alkyl or aralkyl, and has a mean molecular weight \overline{M}_{w} of from 200 to 5,000.

5. A radiation-sensitive mixture as claimed in claim 1, wherein the binder (a) is a poly-(p-hydroxystyrene) or poly-(p-hydroxy-α-methylstyrene) having a mean molecular weight \overline{M}_{w} of from 200 to 30,000.

6. A radiation-sensitive mixture as claimed in claim 1, wherein the binder (a) is a mixture of two or more of the binders stated in claim 2.

7. A radiation-sensitive mixture as claimed in claim 1, wherein the binder (a) is present in an amount of from 50 to 95% by weight, based on the total amount of the radiation-sensitive mixture.

8. A radiation-sensitive mixture as claimed in claim 1, wherein an onium salt of the formula (I) 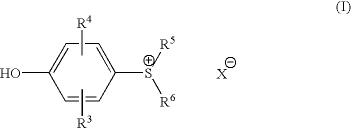
where R³ and R⁴ are identical or different and are each H, OH, alkyl or alkoxy of 1 to 4 carbon atoms, R⁴ and R⁵ are identical or different and are each methyl, ethyl, phenyl or the radical 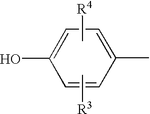
and X^{⊖} is AsF₆^{⊖}, PF₆^{⊖}, SbF₆^{⊖}, BF_{4⊖} or CF₃SO₃^{⊖}, is used as the compound (b) which forms a strong acid on exposure to radiation.

9. A radiation-sensitive mixture as claimed in claim 1, wherein component (b) is present in an amount of from not less than 1 to 30% by weight, based on the total amount of the radiation-sensitive mixture.

10. A radiation-sensitive mixture as claimed in claim 1, wherein a compound of the formula (II) 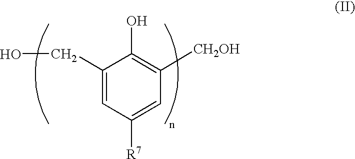
where R⁷ is alkyl of 1 to 4 carbon atoms and n is from 1 to 10, is used as the organic compound (c) capable of undergoing condensation in the presence of an acid.

11. A radiation-sensitive mixture as claimed in claim 1, wherein component (c) is present in an amount of from not less than 3 to 30% by weight, based on the total amount of the radiation-sensitive mixture.

12. A radiation-sensitive mixture as claimed in claim 1, which additionally contains a sensitizer which absorbs radiation and transfers it to component (b).

13. A radiation-sensitive mixture as claimed in claim 1, which contains not more than 1% by weight, based on the total amount of the radiation-sensitive mixture, of additives from the group consisting of the adhesion promoters, surfactants and/or dyes.

14. A process for the preparation of a photosensitive coating material, wherein a radiation-sensitive mixture as claimed in claim 1 is used.

15. A process for the production of a relief structure by application of a radiation-sensitive mixture in a layer thickness of from 0.1 to 5 μm to a conventionally pretreated substrate, drying at from 70 to 120° C., imagewise exposure, heating to 70-160° C. and development using an aqueous alkaline solution, wherein a radiation-sensitive mixture as claimed in claim 1 is used.
